(19) United States
(12) Patent Application Publication
(10) Pub. No.: US 2006/0234410 A1
(43) Pub. Date: Oct. 19, 2006

(54) Method for fabricating organic electroluminescent devices

(75) Inventor: Yun-Sheng Chen, Kaohsiung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU Optronics Corp.

(21) Appl. No.: 11/202,846

(22) Filed: Aug. 12, 2005

(30) Foreign Application Priority Data
Apr. 15, 2005 (TW) 94111989

(51) Int. Cl. H01L 21/265; H01L 21/84

(52) U.S. Cl. 438/45; 438/149; 438/514; 438/527

(57) ABSTRACT

A method for fabricating organic electroluminescent elements comprising an LTPS-TFT as driving circuits. The method comprises providing a substrate, forming an LTPS-TFT on the substrate, and forming an OLED electrically connecting the LTPS-TFT. Specifically, the method for forming a channel region of the LTPS-TFT includes forming a polysilicon layer with a predetermined channel region, and performing an implantation process on the predetermined channel region.

### BACKGROUND

The present invention relates to a method for fabricating organic electroluminescent devices and, more particularly, to a method for fabricating organic electroluminescent device with LTPS-TFTs.

Recently, with the development and wide application of electronic products, such as mobile phones, PDA, and notebook computers, there has been increasing demand for flat display elements which consume less electric power and occupy less space. In flat panel displays, organic electroluminescent elements are self-emitting and highly luminous, with wider viewing angle, faster response speed, and a simple fabrication process, making them popular in the display industry.

An organic light-emitting diode (OLED) using an organic electroluminescent layer is increasingly employed in flat panel displays. In accordance with driving methods, an OLED is an active matrix type (AM-OLED) or a positive matrix type (PM-OLED).

Conventionally, it is known that a positive matrix organic electroluminescent device is driven by XY matrix electrodes to display an image, employing sequential line drive. Therefore, if the number of scanning lines is in hundreds, required instantaneous brightness is several hundred times higher than observed brightness so that electrical current passed instantaneously becomes several hundred times higher and extreme heat is generated resulting in increased operating temperature of the organic electroluminescent layers. However, since the deterioration rate of organic electroluminescent layers is in direct ratio to operating temperature thereof, the luminescent efficiency and lifetime of the organic electroluminescent device are thereby adversely affected.

One trend in organic electroluminescent display technology is for higher luminescent efficiency and longer lifetime. As a result, an active matrix organic electroluminescent device (AM-OLED) with thin film transistors is provided to solve the aforementioned problems. The active matrix organic electroluminescent device provides panel luminescence with thin and lightweight characteristics, spontaneous luminescence with high luminescent efficiency and low driving voltage, and increased viewing angle, high contrast, high-response speed, flexibility and full color. As the need for larger size display devices with higher resolution grows, active matrix organic electroluminescent devices look to achieve a major market trend.

With increased pixel distribution density requirements, low temperature polysilicon (LTPS) process is applied to fabrication of the TFT used in AM-OLED, being substituted for amorphous silicon process. In general, the excimer laser annealing employed by LTPS process, however, crystallizes a silicon layer with laser line beam. Therefore, the energy variation of the laser line beams directly alters the properties of obtained crystalline grains, thereby causing threshold voltage (Vth) and electric current distinctions between obtained TFTS. As well, the luminescent uniformity of AM-OLEDs is reduced.

Referring to FIG. 1, due to the energy variation between each laser beam, the so-called “line mura” defect is clearly observed in the same direction as laser scan in AM-OLEDs employing conventional LTPS-TFTs. Therefore, quality of AM-OLEDs quality is affected adversely by line mura defect.

Therefore, it is necessary to develop a novel LTPS process for an active matrix organic electroluminescent device to prevent an OLED from being affected by the energy variation in the laser line beams.

### SUMMARY

Embodiments of the invention provide a method of fabricating an organic electroluminescent device, comprising the following steps. A low temperature polysilicon thin film transistor (LTPS-TFT) is formed on a substrate to serve as driving circuit, wherein the LTPS-TFT comprises a channel region, a source electrode, and a drain electrode. An organic electroluminescent element is formed on the substrate, wherein the organic electroluminescent element comprises an anode coupled to the drain electrode. Specifically, the method of forming the channel region can comprise forming a polysilicon layer with a predetermined channel region, and ion-implantating to the predetermined channel region. Since the carrier concentration of the channel regions can be tuned by ion-implantation to maintain uniform threshold voltage of each LTPS-TFTs, the line mura problem of the organic electroluminescent device is solved.

According to embodiments of the invention, the ion-implantation process can comprise a p-type ion-implantation, an n-type ion-implantation, or both. Furthermore, the p-type ion-implantation can be Boron-ion implantation, and the n-type ion-implantation process can be phosphorous-ion implantation.

According to some embodiment of the invention, the ion-implantation process can comprise sequentially performing a Boron-ion implantation and phosphorous-ion implantation on the predetermined channel region. Moreover, the ion-implantation process can comprise sequential phosphorous-ion implantation and Boron-ion implantation on the predetermined channel region. It should be noted that the dosage of the ion-implantation process can be 1.0×10¹⁰˜1.0×10²⁰ ion/cm².

A detailed description is given in the following with reference to the accompanying drawings.

### BRIEF DESCRIPTION OF THE DRAWINGS

The invention can be more fully understood by reading the subsequent detailed description in conjunction with the examples and references made to the accompanying drawings, wherein:

FIG. 1 is a photograph of an operating organic electroluminescent device with conventional LTPS-TFTs.

FIG. 2 is a cross section of an organic electroluminescent device according to an embodiment of the invention.

FIG. 3 is a photograph of an operating organic electroluminescent device of FIG. 2.

FIG. 4 is a graph plotting current variation of conventional organic electroluminescent elements and embodiments of the invention against energy variation of conventional excimer laser annealing.

### DETAILED DESCRIPTION

The method of fabricating the organic electroluminescent device 100 according to an embodiment of the invention is described as follows.

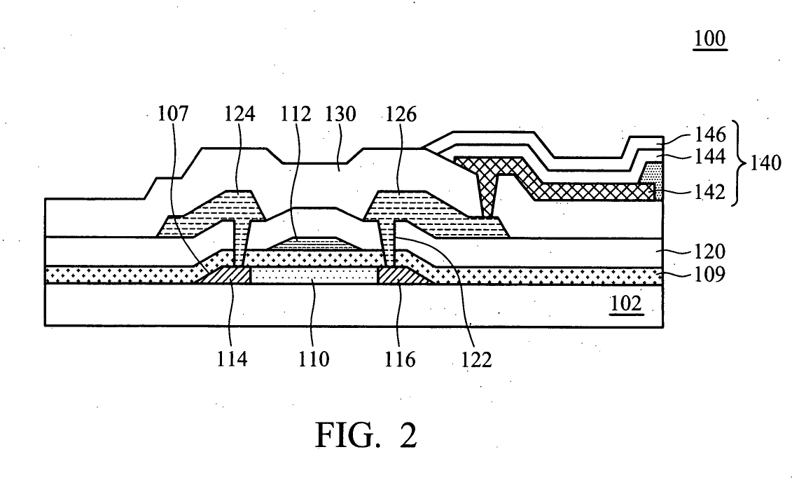

As shown in FIG. 2, the organic electroluminescent device 100 comprises a substrate 102, of an insulating material such as glass, plastic, or ceramic. Furthermore, the substrate 12 can be a semiconductor substrate, such as silicon substrate. A patterned low temperature polysilicon layer 107 is formed on the substrate 102, comprising a predetermined source region (not shown), a predetermined drain region (not shown), and a channel region 110. For example, the low temperature polysilicon layer 107 can comprise an amorphous silicon layer treated by thermal application or excimer laser annealing (ELA) to crystallize the amorphous silicon layer through solid or liquid phase growth.

A gate insulating layer 109 is formed to cover the polysilicon layer 107. Next, a patterned photoresist layer (not shown) is formed, completely covering the predetermined source region and the predetermined drain region. Next, ion-implantation is performed on the channel region 110 with the patterned photoresist layer acting as a mask. The ion-implantation comprises p-type ion-implantation and n-type ion-implantation simultaneously. Herein, the steps of the ion-implantation comprise implanting phosphorous-ion at a dose of 8×10¹¹ ions/cm², and subsequently implanting boron-ion at a dose of 8×10¹¹ ions/cm². The patterned photoresist layer prevents the predetermined source region and the predetermined drain region from being affected by the implantation process.

After removing the patterned photoresist layer, a gate electrode 112 is formed on the gate insulating layer 109. Next, source and drain electrodes 114 and 116 are formed by doping the predetermined source region and the predetermined drain region with the gate electrode 112 as a mask. The gate electrode 112, the source electrode 114, the drain electrode 116, the gate insulating layer 109, and the channel region 110 thus comprise a LTPS-TFT.

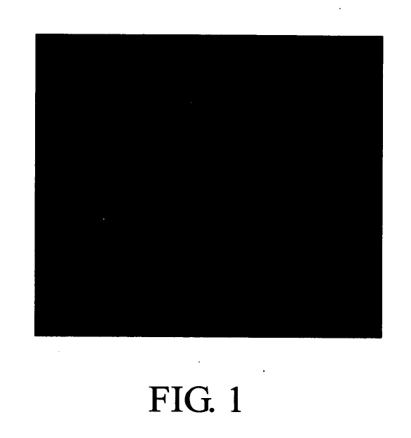

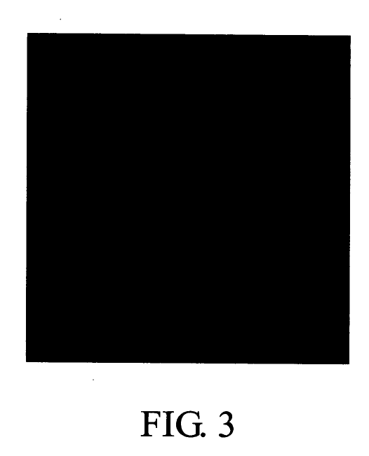

Next, a dielectric layer 120 is formed on the substrate 102, and etched by photolithography to form a plurality of via holes 122, exposing the top surface of the source and drain electrodes 114 and 116. Next, source and drain regions 124 and 126 are formed on the dielectric layer 120 and filled into the via holes 122, respectively electrically connecting the source and drain electrodes 114 and 116. An isolation layer 130 is formed thereon, and an organic electroluminescent element 140 is formed on the isolation layer 130, wherein the organic electroluminescent element 140 comprises an anode electrode 142, electroluminescent layers 144, and a cathode electrode 146. Specifically, the anode electrode 142 is electrically connected to the drain region 126. Thus, fabrication of the thin film transistor is completed. As shown in FIG. 3, the luminescent uniformity of the AM-OLED according to embodiments of the invention is improved, compared with FIG. 1. Namely, the line mura problem of the organic electroluminescent device is solved.

Tables 1 and 2 illustrate the electronic characteristics of a conventional AM-OLED and an AM-OLED according to an embodiment of the invention, respectively.

TABLE 1

| Thickness | | | | | | | | | | | | |
|---|---|---|---|---|---|---|---|---|---|---|---|---|
| of | | | | | | | | | | | | |
| channel | | | | | | | | | | | | |
| region | NMOS | | | | | | PMOS | | | | | |
| (nm) | Vtn | 3σ | Mobilty | 3σ | SS | 3σ | Vtn | 3σ | Mobilty | 3σ | SS | 3σ |
| 490 | 2.75 | 0.32 | 141.94 | 17.71 | 0.25 | 0.03 | −2.92 | 0.55 | −94.69 | 8.12 | 0.39 | 0.09 |
| 470˜510 | 2.76 | 0.42 | 145.96 | 32.08 | 0.27 | 0.10 | −2.82 | 0.71 | −96.81 | 12.84 | 0.38 | 0.08 |
| 450˜530 | 2.72 | 0.40 | 139.07 | 82.49 | 0.27 | 0.09 | −2.87 | 0.85 | −93.48 | 28.42 | 0.39 | 0.11 |

TABLE 2

| Thickness | | | | | | | | | | | | |
|---|---|---|---|---|---|---|---|---|---|---|---|---|
| of | | | | | | | | | | | | |
| channel | | | | | | | | | | | | |
| region | NMOS | | | | | | PMOS | | | | | |
| (nm) | Vtn | 3σ | Mobilty | 3σ | SS | 3σ | Vtn | 3σ | Mobilty | 3σ | SS | 3σ |
| 490 | 2.61 | 0.44 | 144.50 | 15.34 | 0.24 | 0.04 | −2.90 | 0.40 | −91.61 | 8.38 | 0.33 | 0.05 |
| 470˜510 | 2.74 | 0.51 | 137.62 | 30.60 | 0.25 | 0.07 | −3.02 | 0.42 | −86.87 | 12.85 | 0.34 | 0.06 |
| 450˜530 | 2.76 | 0.50 | 134.93 | 59.86 | 0.26 | 0.07 | −3.08 | 0.50 | −84.63 | 18.05 | 0.35 | 0.06 |

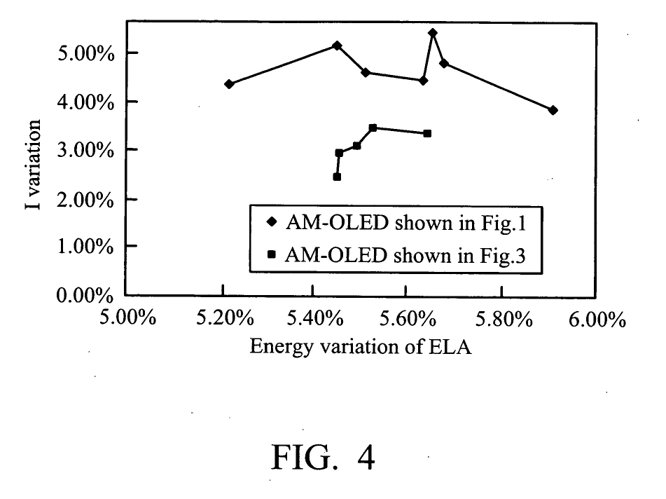

Furthermore, FIG. 4 plots current variation of organic electroluminescent elements of FIG. 1 (conventional AM-OLED) and FIG. 3 (AM-OLED of embodiments) against energy variation of excimer laser annealing. According to Tables 1-2 and FIG. 4, the AM-OLED of the present invention has more uniform electronic characteristics than the conventional AM-OLED.

While the invention has been described by way of example and in terms of preferred embodiment, it is to be understood that the invention is not limited thereto. It is therefore intended that the following claims be interpreted as covering all such alteration and modifications as fall within the true spirit and scope of the invention.

What is claimed is:

1. A method for fabricating an organic electroluminescent device, comprising:
providing a substrate;
forming a low temperature polysilicon thin film transistor (LTPS-TFT) including a channel region, a source electrode, and a drain electrode on the substrate;
forming an organic electroluminescent element on the substrate, wherein the organic electroluminescent element comprises an anode coupled to the drain electrode,
wherein a method of forming the channel region comprises:
forming a polysilicon layer with a predetermined channel region; and
performing an ion-implantation into the predetermined channel region.

2. The method as claimed in claim 1, wherein the ion-implantation comprises p-type ion-implantation.

3. The method as claimed in claim 2, wherein the p-type ion-implantation is Boron-ion implantation.

4. The method as claimed in claim 1, wherein the ion-implantation comprises n-type ion-implantation.

5. The method as claimed in claim 4, wherein the n-type ion-implantation process is phosphorous-ion implantation.

6. The method as claimed in claim 1, wherein the ion-implantation comprises a p-type ion-implantation and an n-type ion-implantation.

7. The method as claimed in claim 1, wherein the ion-implantation comprises a Boron-ion implantation and a phosphorous-ion implantation.

8. The method as claimed in claim 1, wherein the step of performing the ion-implantation comprises sequentially performing a boron-ion implantation and a phosphorous-ion implantation into the predetermined channel region.

9. The method as claimed in claim 1, wherein the step of performing the ion-implantation process comprises sequentially performing a phosphorous-ion implantation and a boron-ion implantation into the predetermined channel region.

10. The method as claimed in claim 1, wherein the implantation dose of the ion-implantation process is substantially between 1.0×10¹⁰ ion/cm² and 1.0×10²⁰ ion/cm².
